(19) United States
(12) Patent Application Publication
(10) Pub. No.: US 2010/0233592 A1
(43) Pub. Date: Sep. 16, 2010

(54) PHOTOMASK AND METHOD OF FORMING PHOTOMASK

(75) Inventor: Fumitake TAGAWA, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/722,024

(22) Filed: Mar. 11, 2010

(30) Foreign Application Priority Data
Mar. 12, 2009 (JP) P2009-059515

(51) Int. Cl. G03F 1/00

(52) U.S. Cl. 430/5

(57) ABSTRACT

A photomask includes a resolution pattern, and a non-resolution pattern. The non-resolution pattern has a center portion and first and second side portions. The first and second side portions are each greater in distance from the resolution pattern than the center portion.

### BACKGROUND OF THE INVENTION

1. Field of the Invention

The present invention relates to a photomask and a method of forming the photomask.

Priority is claimed on Japanese Patent Application No. 2009-59515, filed Mar. 12, 2009, the content of which is incorporated herein by reference.

2. Description of the Related Art

Semiconductor device manufacturing process generally uses the following method. A circuit pattern is formed on a photomask or a photo reticle, so that the pattern is transferred onto a semiconductor substrate. The transfer is made using photolithography technology.

In the photomask fabricating process, a metal film such as molybdenum or molybdenum silicide functioning as a light shielding film is deposited on a transparent substrate such as a glass substrate. A resist film or a photosensitive resin film is provided on the metal film. A pattern is drawn on the resist film using electron beam exposure or the like, based on the layout data for the circuit pattern. The metal film is patterned by etching the metal film using a developed resist pattern as a mask. As a result, a photomask having a desired circuit pattern can be formed. These are disclosed in Japanese Patent Application Laid-open No. 2008-275934.

To transfer a fine circuit pattern formed on the photomask onto the semiconductor substrate as accurately as possible, a photomask obtained by applying optical proximity correction (OPC) is widely used.

When the pattern is transferred onto the semiconductor substrate using the photomask as the OPC technique, a subsidiary pattern or non-resolution pattern having a dimension not to be resolved may be arranged adjacent to the circuit pattern to be formed. These are disclosed in Japanese Patent Application Laid-open No. 2002-357892. By appropriately arranging the non-resolution pattern, it is possible to suppress variation in the line width of the transfer pattern generated by variation in the focal depth during exposure.

In order to prevent the unresolved line pattern or the subsidiary pattern for the OPC from being transferred onto the semiconductor substrate during the exposure, it is preferable that the pattern has a dimension equal to or smaller than 80% of the resolution limit dimension such as the line width.

### SUMMARY

In one embodiment, a photomask may include, but is not limited to, a resolution pattern, and a non-resolution pattern. The non-resolution pattern has a center portion and first and second side portions. The first and second side portions are each greater in distance from the resolution pattern than the center portion.

In another embodiment, a photomask may include, but is not limited to, a transparent substrate, a first pattern for wiring, and a second pattern for an optical proximity correction. The first pattern may be disposed on the transparent substrate. The first pattern may include, but is not limited to, a first line portion which extends in a first direction. The second pattern may be disposed on the transparent substrate. The second pattern may be distanced from the first pattern. The second pattern may include, but is not limited to, a bent portion having the center portion and the first and second side portions. The first and second side portions are greater in distance from the first pattern than the center portion.

In still another embodiment, a method of forming a photomask may include, but is not limited to, the following processes. A metal film is formed on a transparent substrate. A resist pattern is formed on the metal film. The metal film is patterned using the resist pattern as a mask to form a resolution pattern and a non-resolution pattern on the transparent substrate. The non-resolution pattern is distanced from the resolution pattern. The non-resolution pattern has a center portion and first and second side portions. The non-resolution pattern is bent so that the first and second side portions are greater in distance from the resolution pattern than the center portion.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentary cross sectional elevation view illustrating a step involved in a process for forming a photomask in accordance with a first preferred embodiment of the present invention;

FIG. 1B is a fragmentary cross sectional elevation view illustrating a step, subsequent to the step of FIG. 1A, involved in the process for forming the photomask in accordance with the first preferred embodiment of the present invention;

FIG. 1C is a fragmentary cross sectional elevation view illustrating a step, subsequent to the step of FIG. 1B, involved in the process for forming the photomask in accordance with the first preferred embodiment of the present invention;

FIG. 1D is a fragmentary cross sectional elevation view illustrating a step, subsequent to the step of FIG. 1C, involved in the process for forming the photomask in accordance with the first preferred embodiment of the present invention;

FIG. 2 is a plan view illustrating a photomask in accordance with the first preferred embodiment of the present invention;

FIG. 3 is a plan view illustrating a photomask in accordance with the related art;

FIG. 4 is a plan view illustrating a photomask in accordance with a first modified embodiment of the present invention;

FIG. 5 is a plan view illustrating a photomask in accordance with a second modified embodiment of the present invention;

FIG. 6 is a plan view illustrating a photomask in accordance with the related art;

FIG. 7 is a plan view illustrating a non-resolution pattern of the photomask of FIG. 6;

FIG. 8 is a plan view illustrating a partially peeled non-resolution pattern and a resolution pattern of a photomask in accordance with the related art; and

FIG. 9 is a plan view illustrating a partially peeled non-resolution pattern and a resolution pattern of a photomask in accordance with the related art.

### DETAILED DESCRIPTION OF THE PREFERRED EMBODIMENTS

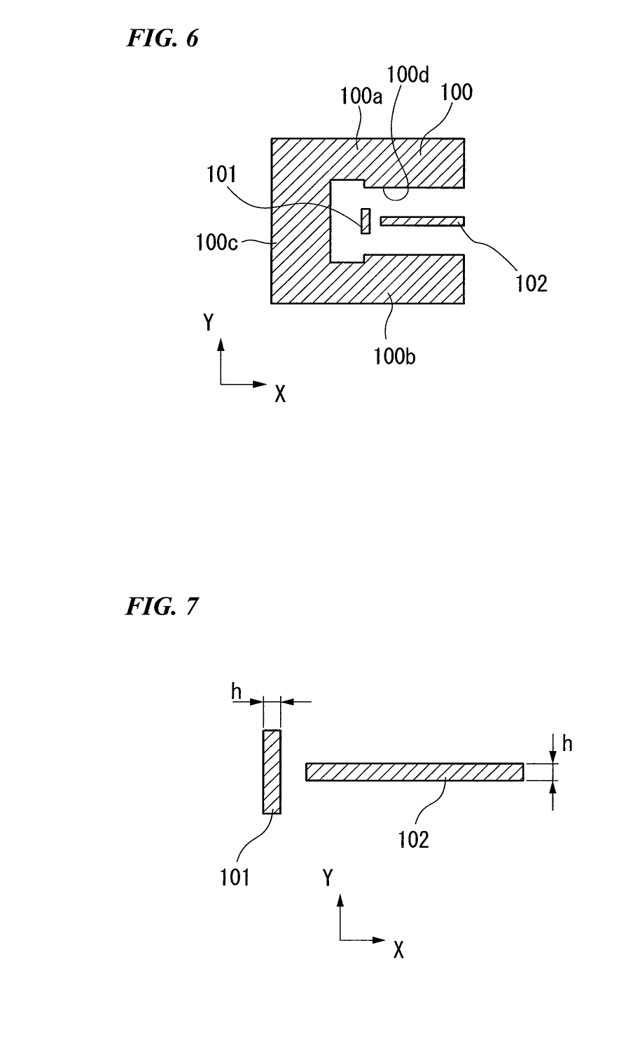

Before describing the present invention, the related art will be explained in detail with reference to FIGS. 6, 7, 8 and 9, in order to facilitate the understanding of the present invention.

The recent development in a micro-technology leads to that the dimension (line width) of the non-resolution pattern becomes smaller. The following problems will occur when the non-resolution pattern having a small dimension is formed on the photomask.

With reference to FIG. 6, a resolution pattern 100 for wiring and first and second non-resolution patterns 101 and 102 having linear shapes are formed on the photomask. The resolution pattern 100 for wiring is a pattern of the light shielding film on the photomask corresponding to the wiring pattern or circuit pattern formed on the semiconductor substrate. The first and second non-resolution patterns 101 and 102 are light shielding patterns that are provided to correct the optical proximity effect for the resolution pattern 100 for wiring. The first and second non-resolution patterns 101 and 102 are formed in parallel to the lines that form the resolution pattern 100 for wiring.

All of the resolution pattern 100 for wiring and the first and second non-resolution patterns 101 and 102 provide the light shielding area in the photomask. The resolution pattern 100 for wiring and the first and second non-resolution patterns 101 and 102 are formed by forming a resist pattern on the metal film on the transparent substrate and by patterning the metal film by using this resist pattern as a mask.

The resolution pattern 100 for wiring shown in FIG. 6 includes first and second wiring portions 100a and 100b extending in the x-direction in the drawing and third wiring portion 100c extending in the y-direction in the drawing. The first and second wiring portions 100a and 100b are arranged with a predetermined interval. Ends of the first and second wiring portions 100a and 100b are connected to each other with the third wiring portion 100c. The first and second non-resolution patterns 101 and 102 are arranged within a space 100d surrounded by the first to third wiring portions 100a to 100c.

FIG. 7 is an enlarged diagram illustrating the first and second non-resolution patterns 101 and 102. The line widths of the first and second non-resolution patterns 101 and 102 are set to the same value h. The first non-resolution pattern 101 is a linear shape pattern extending in the y-direction in the drawing. The second non-resolution pattern 102 is a linear shape pattern extending in the x-direction in the drawing. The first and second non-resolution patterns 101 and 102 are separated from each other. The non-resolution patterns 101 and 102 can be determined using a simulation method known in the art.

The resist patterns for forming the respective patterns 100, 101, and 102 are formed as follows. First, the resist film is deposited on the entire surface of the metal film. Then, the resist film is patterned using electron beams and exposed. Subsequently, the exposed resist film is developed.

In the development process when the resist patterns for forming the respective patterns 100, 101, and 102 are provided, since a processing liquid such as a development liquid or a cleaning liquid is adhered between the respective resist patterns, a surface tension of such a processing liquid may be applied between them. Since a contact area between the metal film corresponding to the non-resolution patterns 101 and 102 and the resist patterns are reduced if the line widths h of the non-resolution patterns 101 and 102 are to be fine, an adhesive force between the metal film and the resist film weakens. Particularly, similar to the first non-resolution pattern 101, when an arrangement relationship between the non-resolution pattern and the adjacent resolution pattern 100 for wiring in a direction perpendicular to the line width h is asymmetric, the surface tension of the processing liquid is applied between the resist pattern corresponding to the first non-resolution pattern 101 and the resist pattern corresponding to the resolution pattern 100 for wiring. As a result, this surface tension may make it difficult to form the resist pattern having a desired shape.

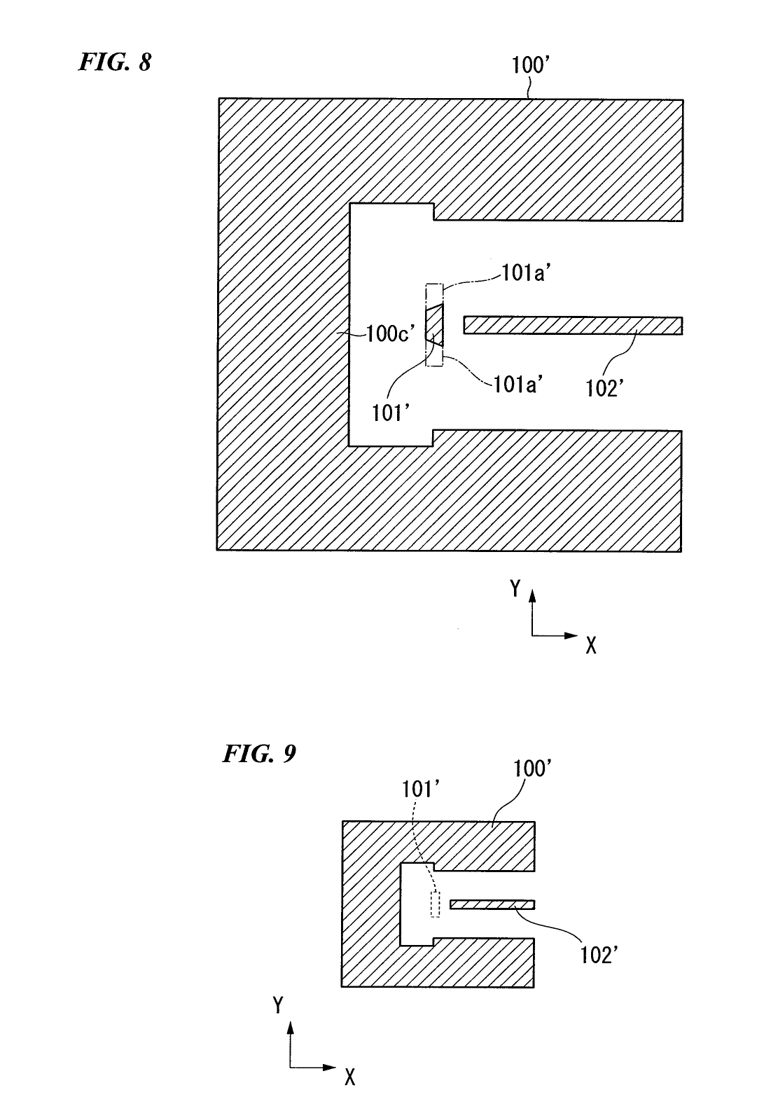

As shown in FIG. 8, both ends 101a′ of the resist pattern 101′ may be peeled due to the surface tension between the resist pattern 101′ of the first non-resolution pattern 101 and the resist pattern 100′ of the resolution pattern 100 for wiring. The reason for this peeling or removal may be considered as follows.

As shown in FIG. 6, a circuit pattern facing the non-resolution pattern 101 is absent in the x-direction of both ends in the longitudinal direction of the first non-resolution pattern 101 while the third wiring portion 100c corresponding to the circuit pattern exists in the opposite direction to the x-direction. Therefore, as shown in FIG. 8, during the exposure and the development of the resist pattern, the surface tension of the processing liquid is strongly applied toward the resist pattern 100c′ of the third wiring portion 100c in both ends 101a′ of the resist pattern 101′ of the first non-resolution pattern 101. The resist film may be peeled due to the effect of this surface tension.

As shown in FIG. 9, as a result of the strong surface tension toward the third wiring portion 100c, the entire resist pattern 101′ of the non-resolution pattern 101 may be perfectly peeled. In addition, the resist pattern 101′ of the non-resolution pattern 101 may be destroyed in that position which is not illustrated.

As described above, the resist pattern for forming the non-resolution pattern 101 has a shape different from the desired shape and then is transferred to the metal film on the photomask in this state. Therefore, it is difficult to form the photomask having the non-resolution pattern of a desired pattern shape.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In one embodiment, a photomask may include, but is not limited to, a resolution pattern, and a non-resolution pattern. The non-resolution pattern has a center portion and first and second side portions. The first and second side portions are each greater in distance from the resolution pattern than the center portion.

In some cases, the non-resolution pattern may be used for an optical proximity correction.

In some cases, the non-resolution pattern may include, but is not limited to, a bent portion having the center portion and the first and second side portions. The first and second side portions are greater in distance from the resolution pattern than the center portion. The bent portion may be a curved portion.

In some cases, the bent portion may include, but is not limited to, a bent alignment of rectangular patterns. In some cases, the bent alignment of rectangular patterns may include, but is not limited to, first and second rectangular patterns which are different in dimension from each other.

In some cases, the bent alignment of rectangular patterns may include, but is not limited to, third and fourth rectangular patterns which are positioned at opposing sides of the bent alignment and a fifth rectangular pattern which is positioned at the center of the bent alignment. The third and fourth rectangular patterns are larger than the fifth rectangular pattern.

In some cases, the bent portion may have a profile of distance from the resolution pattern, such that the distance becomes larger as the position becomes closer to the first and second side portions from the center portion.

In some cases, the bent portion may have an amount of bent which is equal to or less than a line width of the bent portion.

In some cases, the curved portion may be curved so that the center portion is closer to the resolution pattern than the first and second side portions.

In some cases, the non-resolution pattern may have a longitudinal length and a line width. A ratio of the longitudinal length to the line width is equal to or less than 10.

In some cases, the resolution pattern may include, but is not limited to, a first line portion which extends in a first direction. The first line portion is closer to the non-resolution than the other portion of the resolution pattern. The first and second side portions are greater in distance from the first line portion than the center portion.

In some cases, the photomask includes a transparent substrate on which the resolution pattern and the non-resolution pattern are disposed.

In another embodiment, a photomask may include, but is not limited to, a transparent substrate, a first pattern for wiring, and a second pattern for an optical proximity correction. The first pattern may be disposed on the transparent substrate. The first pattern may include, but is not limited to, a first line portion which extends in a first direction. The second pattern may be disposed on the transparent substrate. The second pattern may be distanced from the first pattern. The second pattern may include, but is not limited to, a bent portion having the center portion and the first and second side portions. The first and second side portions are greater in distance from the first pattern than the center portion.

In some cases, the bent portion may have an amount of bent which is equal to or less than a line width of the bent portion.

In some cases, the second pattern has a longitudinal length and a line width. A ratio of the longitudinal length to the line width is equal to or less than 10.

In still another embodiment, a method of forming a photomask may include, but is not limited to, the following processes. A metal film is formed on a transparent substrate. A resist pattern is formed on the metal film. The metal film is patterned using the resist pattern as a mask to form a resolution pattern and a non-resolution pattern on the transparent substrate. The non-resolution pattern is distanced from the resolution pattern. The non-resolution pattern has a center portion and first and second side portions. The non-resolution pattern is bent so that the first and second side portions are greater in distance from the resolution pattern than the center portion.

In some cases, the non-resolution pattern may have a longitudinal length and a line width, a ratio of the longitudinal length to the line width is equal to or less than 10.

In some cases, the non-resolution pattern is arched toward a first direction. A development solution applies a largest surface tension to the resist pattern in the first direction. The resist pattern is used to form the non-resolution pattern.

Hereinafter, embodiments of the present invention will be described with reference to the accompanying drawings.

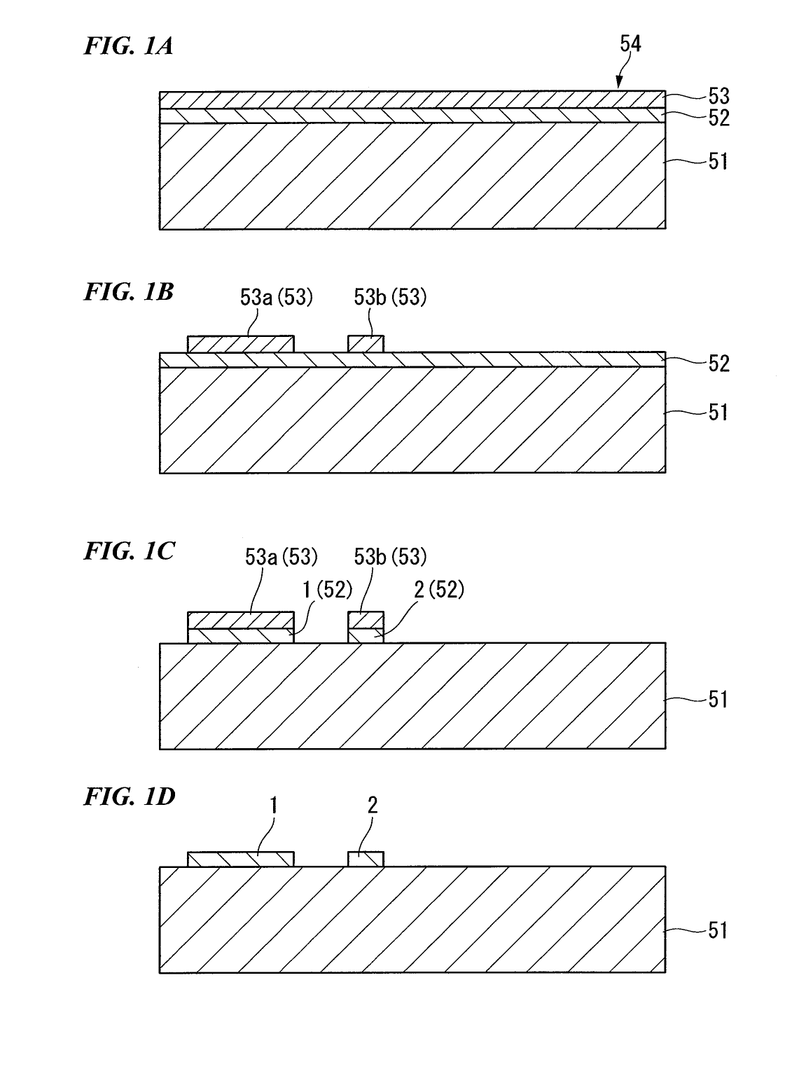

The photomask according to an embodiment of the present invention is manufactured through a depositing process and a development and exposure process. Referring to FIG. 1A, in the depositing process, a metal film 52 and a resist film or a photosensitive resin 53 are sequentially deposited on a transparent substrate 51 such as a glass substrate. As a result, a photomask blank 54 is formed. Since the metal film 52 functions as a light shielding body, it may include molybdenum silicide or chrome. The resist film 53 may be either the positive type or the negative type.

Referring to FIG. 1B, in the exposure and development process, the resist film 53 is exposed by performing electron beam exposure to the resist film 53 of the photomask blank 54. Then, the exposed resist film is developed using a predetermined development liquid so that the resist film 53 is patterned. On the resist film 53 after the patterning, at least the resist pattern 53a corresponding to the resolution pattern for wiring and the resist pattern 53b corresponding to the non-resolution pattern are fabricated.

Referring to FIG. 1C, the metal film 52 is etched by using the patterned resist film 53 as a mask to remove a part of the metal film 52 exposed from the resist film 53 in FIG. 1B.

Referring to FIG. 1D, it is possible to obtain the photomask including the resolution pattern 1 for wiring and the non-resolution pattern 2 by removing the resist film 53. The non-resolution pattern 2 is a pattern separated from the resolution pattern 1 for wiring in order to correct the optical proximity effect of the resolution pattern 1 for wiring.

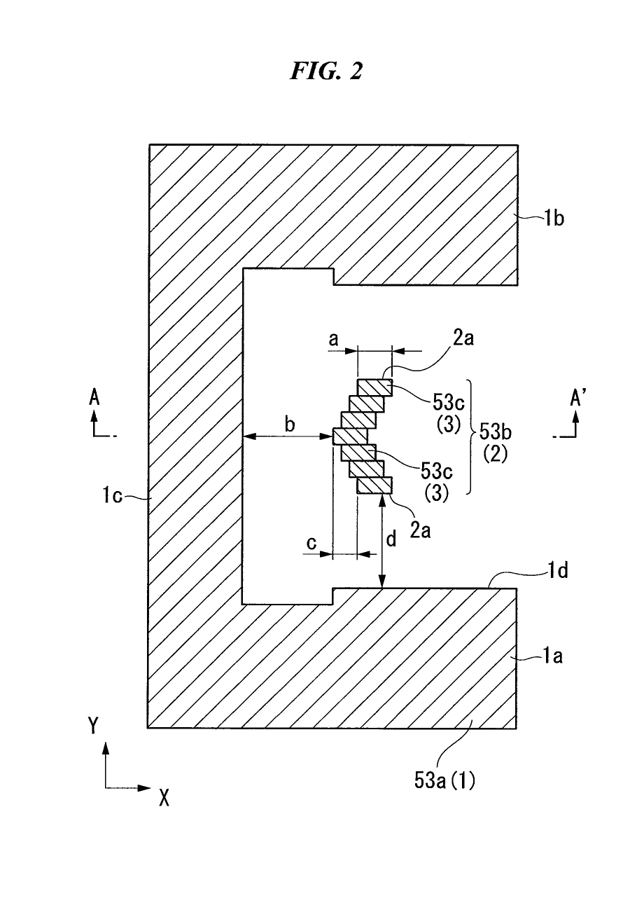

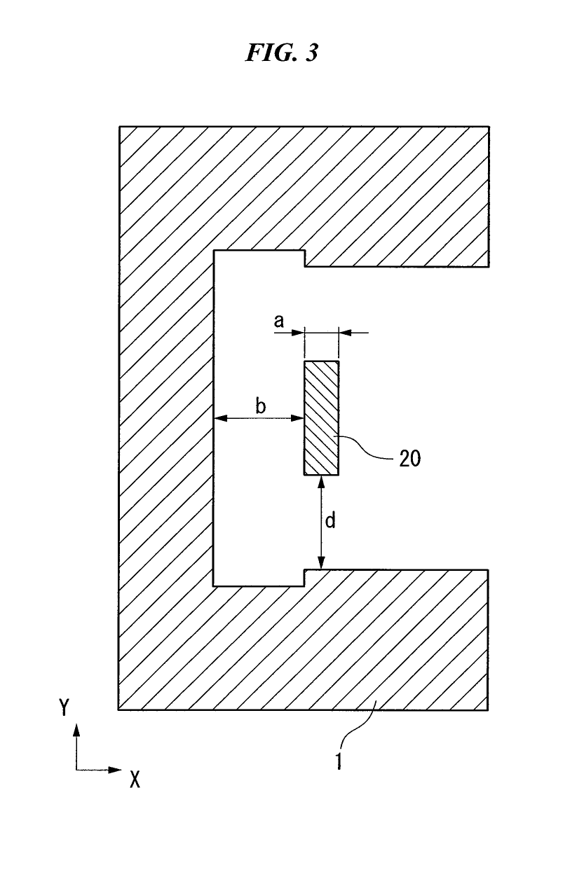

The shape of the resist pattern exposed and developed as shown in FIGS. 1A to 1D will be described with reference to FIG. 2. FIG. 2 is a top plan view of the semiconductor device shown in FIG. 1C. FIG. 1C is a cross-sectional view along an A-A′ line of FIG. 2.

As shown in FIG. 2, the resist film 53 is patterned including the resist pattern 53a corresponding to the resolution pattern 1 for wiring and the resist pattern 53b corresponding to the non-resolution pattern 2. The resolution pattern 1 for wiring and the corresponding resist pattern 53a have nearly the same shape as seen in a plan view. Similarly, the non-resolution pattern 2 and the corresponding resist pattern 53b have nearly the same shape as seen in a plan view.

Referring to FIG. 2, the resolution pattern 1 for wiring underlying the resist pattern 53a includes first and second wiring portions 1a and 1b extending in the x-direction in the drawing and a third wiring portion 1c extending in the y-direction in the drawing. The first and second wiring portions 1a and 1b are arranged with a predetermined interval, and ends of the first and second wiring portions 1a and 1b are connected to each other with the third wiring portion 1c. The non-resolution pattern 2 is arranged within a space 1d surrounded by the first to third wiring portions 1a to 1c. The non-resolution pattern 2 in FIG. 2 underlies the resist pattern 53b.

As shown in FIGS. 1C and 2, the resolution pattern 1 for wiring formed by the resist pattern 53a is a part of the circuit pattern included in the semiconductor device and also a light shielding area formed by the metal film 52 remaining under the resist pattern 53a. The resist pattern 53a corresponding to the resolution pattern 1 for wiring is drawn in a dimension corresponding to a width equal to or larger than a resolution limit of the exposure apparatus to be used when the semiconductor device is manufactured. In this case, the “resolution limit” means a minimum dimension, for example, a line width allowing the exposure apparatus to form and transfer a pattern onto the semiconductor substrate. In addition, the pattern on the photomask is typically transferred onto the semiconductor substrate using a reduced projection exposure system. Therefore, in practice, the resolution pattern 1 for wiring is arranged on the photomask such that the line width transferred onto the semiconductor substrate has a dimension magnified as much as a reduction rate of the projection exposure system. Therefore, in the following description, “the resolution limit” means a dimension of the pattern formed on the photomask corresponding to a minimum dimension by which a pattern can be formed and transferred onto the semiconductor substrate.

Then, as shown in FIGS. 1C and 2, the non-resolution pattern 2 formed by the resist pattern 53b is arranged adjacent to the resolution pattern 1 for wiring. The non-resolution pattern 2 forms a light shielding area on the photomask similar to the resolution pattern 1 for wiring. The non-resolution pattern 2 is formed to generate the optical proximity correction (OPC) in order to transfer the minute resolution pattern 1 for wiring formed on the photomask onto the semiconductor substrate as accurately as possible.

The non-resolution pattern 2 of the present embodiment has a curved shape along the longitudinal direction such that the end 2a of the resolution pattern 1 for wiring where the OPC effect is applied becomes more distant from the resolution pattern 1 for wiring.

In order to make the non-resolution pattern 2 have a curved shape, it is preferable that the non-resolution pattern 2 is formed as a set of a plurality of rectangular portions or rectangular patterns 3. In FIG. 2, the non-resolution pattern 2 includes seven rectangular portions 3.

In the present embodiment, when a plurality of the non-resolution patterns are provided in a single photomask, it is preferable that at least one of the non-resolution patterns 2 has a curved shape along the longitudinal direction thereof as seen in a plan view.

Such a curved non-resolution pattern 2 is formed by the resist pattern 53b exposed and developed using electron beam drawing or the like. Specifically, when the resist pattern 53b is formed in FIGS. 1B and 1C, the resist pattern 53b including fine patterns 53c is formed by irradiating or exposing electron beams to fine patterns 53c corresponding to the rectangular portions 3 and then developing the exposed fine patterns 53c. Furthermore, the non-resolution pattern 2 is formed by patterning the metal film 52 using the resist pattern 53b as a mask.

In FIG. 2, the width “a” of the rectangular portion 3 in the x-direction is set to a predetermined dimension equal to or smaller than the resolution limit. It is preferable that the amount of curve “c” of the non-resolution pattern 2 is set to a value equal to or smaller than the line width “a” in order to prevent the non-resolution pattern 2 from being transferred onto the semiconductor substrate during the exposure using the photomask. By setting the amount of curve “c” at a value which is equal to or smaller than the line width “a”, it is possible to prevent the OPC effect from being reduced.

Since the length of the rectangular portion 3 in the y-direction is not particularly limited, a desired value may be selected considering drawing efficiency.

As described above, by making the non-resolution pattern 2 as a set of a plurality of rectangular portions 3, it is possible to readily obtain the non-resolution pattern 2 having a curved shape.

For the purpose of comparison, the arrangement of the non-resolution pattern 20 of the related art is shown in FIG. 3. The line width “a” of the non-resolution pattern 20 shown in FIG. 3 is set to a predetermined dimension equal to or smaller than the resolution limit. In addition, distances “b” and “d” from the resolution pattern 1 for wiring are also set to predetermined values considering the OPC effect.

As shown in FIG. 2, in the present embodiment, the distances “b” and “d” from the resolution pattern 1 for wiring and the line width “a” of the non-resolution pattern 2 are set to the same values as those of the related art of FIG. 3. In the present embodiment, the distance between the rectangular portion 3 located in the center of a convex portion of the curved non-resolution pattern 2 and the resolution pattern 1 for wiring is set to the same value of distance b as that of the related art. In addition, the distance between the rectangular portion 3 located in the end of the convex portion of the cured shape and the resolution pattern 1 for wiring is set to the same value of distance d as that of the related art.

In FIG. 3, since both ends of the non-resolution pattern 20 in the y-direction are rounded in the development process of the resist, the adhesive area with the metal film underlying the ends of the resist is reduced. For this reason, as described in conjunction with FIGS. 8 and 9, particularly, the ends of the non-resolution pattern 20 become peeled or deformation due to reduction of the adhesive force.

On the contrary, in the present embodiment, the distance between the end portion of the non-resolution pattern 2 and the facing resolution pattern 1 for wiring becomes b+c, which is larger than the distance “b” of the related art as much as “c” which can be called the amount of curve or the curving factor. Therefore, in the development process of the resist film 53, the surface tension of the processing liquid such as a development liquid between the resolution pattern 1 for wiring and the non-resolution pattern 2 is alleviated. As a result, it is possible to prevent the resist film 53 from being peeled or deformed due to the surface tension of the development liquid or the like.

Through the aforementioned process, the resolution pattern 1 for wiring and the non-resolution pattern 2 having a curved shape are formed on the photomask in the present embodiment.

In the present embodiment, it is preferable that the non-resolution pattern 2 is curvedly arranged to have a convex shape protruded toward a direction where the largest surface tension is applied based on the arrangement relationship between the non-resolution pattern 2 and the facing resolution pattern 1 for wiring. That is, it is preferable that the curved direction is determined considering the length of the facing resolution pattern 1 for wiring and the distance of the non-resolution pattern 2.

In the present embodiment, it is not necessary that all of the non-resolution patterns are curved.

For example, in the non-resolution pattern 102 shown in FIGS. 6 and 7, the first and second wiring portions 100a and 100b of the resolution pattern 100 for wiring are arranged evenly with the same distance in a direction such as y-direction perpendicular to the line-extending direction such as x-direction. In this case, it is not necessary to curve the non-resolution pattern 102.

When the non-resolution pattern is a linear pattern which has a long longitudinal length, the resist pattern has an increased adhesion area. Therefore, the entire resist pattern is not easily peeled. As a result, particularly, in the non-resolution pattern having a ratio such as an aspect ratio of the longitudinal dimension to the line width of the resist pattern is equal to or smaller than 10, it is preferable that the shape of the non-resolution pattern is curved as seen in a plan view.

### MODIFIED EXAMPLES

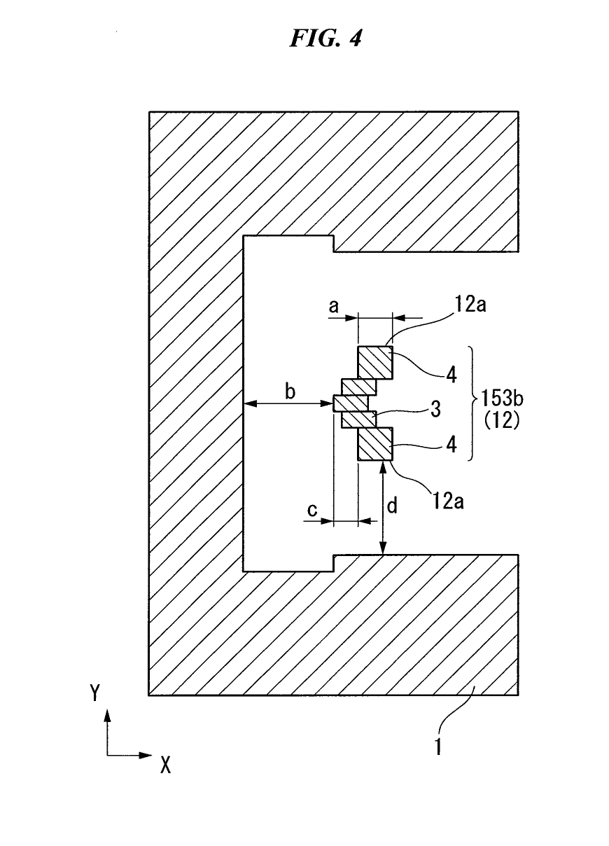

The rectangular portions formed to curve the non-resolution pattern may have either the same or different shapes. FIG. 4 illustrates an example where the rectangular portions 4 arranged in both ends 12a in the y-direction of the non-resolution pattern 12 are larger than other rectangular portions 3 in the y-direction. As a result, even when the corner portions of the resist pattern 153b are rounded in the development process, it is possible to obtain a stronger adhesive force than the case of FIG. 2. Therefore, in this case, it is possible to more significantly prevent deformation in the resist pattern 153b.

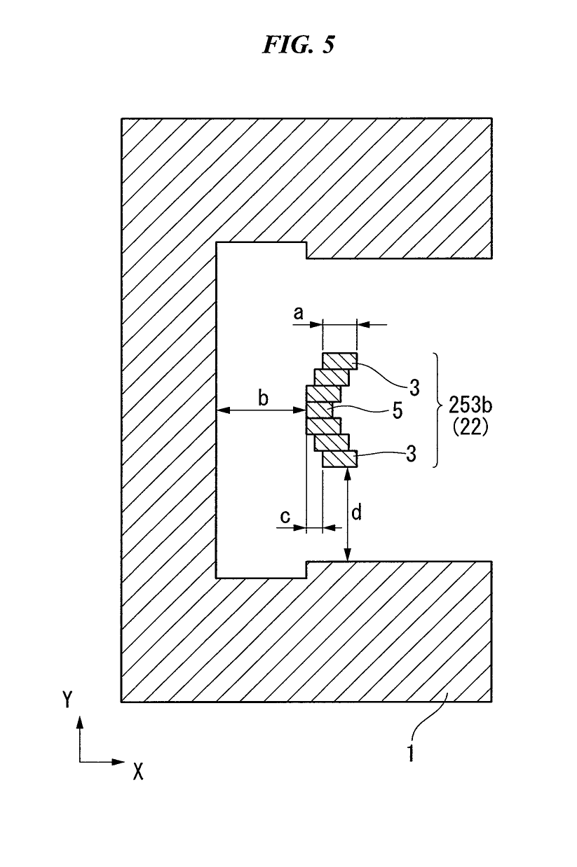

FIG. 5 illustrates an arrangement where the rectangular portion 5 arranged in the center of the non-resolution pattern 22 is arranged in a shorter distance than other rectangular portions 3 in the x-direction, and the apex of the convex shape in the center of the curved shape is removed. As a result, the amount of curve “c” is reduced in comparison with the curve of FIG. 2. This arrangement can be applied instead of controlling the amount of deviation of each rectangular portion 3.

In order to provide the curved non-resolution patterns 2, 12, and 22 of the present invention as data used in the electron beam (EB) drawing, a design rule check (DRC) is performed for the mask data after the drawing data of the non-resolution pattern having only the linear shape of the related art are created. In this case, it is preferable that a location relationship between the size of the non-resolution pattern and the adjacent circuit pattern is extracted, and the curving process is applied to only the non-resolution pattern satisfying particular criteria established previously. For example, it is preferable that the curving process is applied to the non-resolution pattern of which a ratio such as an aspect ratio of the longitudinal dimension to the line width of the resist pattern is equal to or smaller than 10.

As described above, according to the present embodiment, it is possible to prevent deformation of the non-resolution pattern 2 during the process of forming the photomask and readily manufacture the photomask having a desired characteristic by allowing the non-resolution pattern 2 formed on the photomask to have a curved shape.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

The term “bent” as used herein means “not-straight”. The shape of “bent” may include any shapes of non-straight such as a curved shape and an angled shape, but is not limited thereto.

It is apparent that the present invention is not limited to the above embodiments, but may be modified and changed without departing from the scope and spirit of the invention.

What is claimed is:

1. A photomask comprising:
a resolution pattern; and
a non-resolution pattern having a center portion and first and second side portions, the first and second side portions being greater in distance from the resolution pattern than the center portion.

2. The photomask according to claim 1, wherein the non-resolution pattern is disposed based on an optical proximity correction.

3. The photomask according to claim 1, wherein the non-resolution pattern comprises a bent portion having the center portion and the first and second side portions, the first and second side portions are greater in distance from the resolution pattern than the center portion.

4. The photomask according to claim 3, wherein the bent portion is a curved portion.

5. The photomask according to claim 3, wherein the bent portion comprises a bent alignment of rectangular patterns.

6. The photomask according to claim 5, wherein the bent alignment of rectangular patterns comprises first and second rectangular patterns which are different in dimension from each other.

7. The photomask according to claim 5, wherein the bent alignment of rectangular patterns comprises third and fourth rectangular patterns which are positioned at opposing sides of the bent alignment and a fifth rectangular pattern which is positioned at the center of the bent alignment, and the third and fourth rectangular patterns are larger than the fifth rectangular pattern.

8. The photomask according to claim 5, wherein the bent portion has a profile of distance from the resolution pattern, such that the distance becomes larger as the position becomes closer to the first and second side portions from the center portion.

9. The photomask according to claim 4, wherein the bent portion has an amount of bent which is equal to or less than a line width of the bent portion.

10. The photomask according to claim 3, wherein the curved portion is curved so that the center portion is closer to the resolution pattern than the first and second side portions.

11. The photomask according to claim 1, wherein the non-resolution pattern has a longitudinal length and a line width, a ratio of the longitudinal length to the line width is equal to or less than 10.

12. The photomask according to claim 1, wherein the resolution pattern comprises a first line portion which extends in a first direction, the first line portion is closer to the non-resolution than the other portion of the resolution pattern, and
the first and second side portions are greater in distance from the first line portion than the center portion.

13. The photomask according to claim 1, further comprising:
a transparent substrate on which the resolution pattern and the non-resolution pattern are disposed.

14. A photomask comprising:
a transparent substrate;
a first pattern disposed on the transparent substrate for wiring, the first pattern comprising a first line portion which extends in a first direction; and
a second pattern disposed on the transparent substrate for an optical proximity correction, the second pattern being distanced from the first pattern, the second pattern comprising a bent portion having the center portion and the first and second side portions, the first and second side portions are greater in distance from the first pattern than the center portion.

15. The photomask according to claim 14, wherein the bent portion has an amount of bent which is equal to or less than a line width of the bent portion.

16. The photomask according to claim 14, wherein the second pattern has a longitudinal length and a line width, a ratio of the longitudinal length to the line width is equal to or less than 10.

17. The photomask according to claim 14, wherein the first pattern is a resolution pattern and the second pattern is a non-resolution pattern.

18. A method of forming a photomask, the method comprising:
forming a metal film on a transparent substrate;
forming a resist pattern on the metal film; and
patterning the metal film using the resist pattern as a mask to form a resolution pattern and a non-resolution pattern on the transparent substrate,
wherein the non-resolution pattern is distanced from the resolution pattern, the non-resolution pattern has a center portion and first and second side portions, the non-resolution pattern is bent so that the first and second side portions are greater in distance from the resolution pattern than the center portion.

19. The method according to claim 18, wherein the non-resolution pattern has a longitudinal length and a line width, a ratio of the longitudinal length to the line width is equal to or less than 10.

20. The method according to claim 18, wherein the non-resolution pattern is arched toward a first direction, a development solution applies a largest surface tension to the resist pattern in the first direction, the resist pattern is used to form the non-resolution pattern.
